(19) United States
(12) Patent Application Publication
(10) Pub. No.: US 2024/0319582 A1
(43) Pub. Date: Sep. 26, 2024

(54) Optical Component with Apodized Mask

(71) Applicant: Apple Inc., Cupertino, CA (US)

(72) Inventors: Takeyoshi Saiga, Taito-ku (JP); Yoshikazu Shinohara, Cupertino (CA); Alexander Feldman, Los Altos, CA (US); Liangyu Qiu, Santa Clara, CA (US); Junkyo Suh, Palo Alto, CA (US); Yuhong Yao, Tracy, CA (US); Milan Maksimovic, Sunnyvale, CA (US); Moshe Kriman, Tel Aviv (IL); Dana Gal-Fuss, Tel Aviv (IL); Refael Della Pergola, Jerusalem (IL); Maoz Ovadia, Kiryat Ono (IL); Aharon R. Barnea, Ramat Gan, IL (US)

(21) Appl. No.: 18/600,273

(22) Filed: Mar. 8, 2024

Related U.S. Application Data
(60) Provisional application No. 63/453,620, filed on Mar. 21, 2023.
(60) Provisional application No. 63/535,970, filed on Aug. 31, 2023.

(51) Int. Cl. G03F 1/38; G02B 5/04; G03B 17/12; G03F 1/54

(52) U.S. Cl. CPC G03F 1/38; G02B 5/04; G03B 17/12; G03F 1/54

(57) ABSTRACT

An optical component includes a mask defining a light blocking portion and a light transmitting portion of the optical component. The light blocking portion is separated from the light transmitting portion by one or more mask edges, at least one of which is defined by an apodized pattern. The apodized pattern of the mask edge reduces diffraction and thus flare caused by the mask.

### CROSS-REFERENCE TO RELATED APPLICATIONS

This application is a nonprovisional and claims the benefit under 35 U.S.C. 119(e) of U.S. Provisional Patent Application No. 63/453,620, filed Mar. 21, 2023, and U.S. Provisional Patent Application No. 63/535,970, filed Aug. 31, 2023, the contents of which are incorporated herein by reference as if fully disclosed herein.

### TECHNICAL FIELD

Embodiments described herein relate to optical components, and in particular to optical components including a mask having at least one mask edge defined by an apodized pattern.

### BACKGROUND

Optical components such as lenses are widely used in electronic devices as part of optical systems, which may be used for capturing images and/or projecting light. As electronic devices continue to shrink in size, optical systems, and thus the optical components in these optical systems, continue to increase in complexity to provide the same or improved performance in a smaller package size. One way to decrease the package size of an optical system along one or more dimensions is to use folding optics, such as a prism, to fold light along one or more additional axes from an initial axis along which light enters the optical system. However, folding optics may suffer from performance issues such as flare. There is thus a continuing need for optical components and systems for reducing a package size along one or more dimensions while maintaining or improving optical performance.

### SUMMARY

Embodiments described herein relate to optical components, and in particular to optical components including a mask having at least one mask edge defined by an apodized pattern. In one embodiment, an optical component includes a component body and a mask. The component body may comprise an optically transparent material. The mask may define a light blocking portion and a light transmitting portion of a plane of the component body. The light blocking portion may be separated from the light transmitting portion by one or more edges of the mask. At least one of the one or more edges of the mask may be defined by an apodized pattern.

In one embodiment, the light transmitting portion of the plane is rectangular.

In one embodiment, the component body comprises glass.

In one embodiment, the light blocking portion of the plane is separated from the light transmitting portion of the plane by a first mask edge and a second mask edge. In a first embodiment, the first mask edge is defined by an apodized pattern, while the second mask edge is defined by a straight line. In a second embodiment, the first mask edge and the second mask edge are defined by an apodized pattern.

In one embodiment, the optical component further comprises an additional mask. The additional mask defines a light blocking portion and a light transmitting portion of an additional plane of the component body. The light blocking portion of the additional plane is separated from the light transmitting portion of the additional plane by one or more edges of the additional mask. At least one of the one or more edges of the additional mask may be defined by an apodized pattern. In one embodiment, the at least one of the one or more edges of the mask is defined by a different apodized pattern than the at least one of the one or more edges of the additional mask. In one embodiment, the plane and the additional plane are parallel.

In one embodiment, the optical assembly is a prism.

In one embodiment, the apodized pattern is a repeating pattern with a varying peak-to-peak amplitude. Additionally or alternatively, the apodized pattern is a repeating pattern with a varying period.

In one embodiment, the mask includes a distribution of openings positioned in the light blocking portion. Additionally or alternatively, the mask includes a distribution of mask pieces positioned in the light transmitting portion.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIG. 1A shows a rear view of an exemplary electronic device, such as described herein.

FIG. 1B is a block diagram illustrating components of the exemplary electronic device, such as described herein.

FIG. 2 is a cross-sectional side view of an exemplary optical system, such as described herein.

FIG. 3A is an isometric view of an exemplary optical component, such as described herein.

FIG. 3B is a cross-sectional view of an exemplary optical component, such as described herein.

FIG. 3C is an exploded view of an exemplary optical component, such as described herein.

FIGS. 4A-4C illustrate various designs for a mask including an apodized edge for an optical component, such as described herein.

FIGS. 5A-5C illustrate various designs for a mask including apodized edges for an optical component, such as described herein.

FIG. 6 is a flowchart depicting example operations of a method for manufacturing an optical component including a mask having one or more apodized edges, such as described herein.

FIGS. 7A-7C illustrate various designs for a mask including an apodized edge with a varying pattern for an optical component, such as described herein.

FIGS. 8A-8C illustrate designs for a mask including an apodized edge for an optical component such as described herein.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to optical components, and in particular to optical components including a mask having at least one mask edge defined by an apodized pattern.

Optical components such as lenses may form part of an optical system, which may be used to focus and/or direct light for a camera or a projector. Recently, folding optics, or optical components that fold light along one or more additional axes from an initial axis along which light enters the system, have been used to reduce the package size of an optical system along one or more dimensions while maintaining focal length. However, folding optics, such as prisms, often suffer from performance issues such as flare. Embodiments of the present disclosure relate to optical components for reducing the footprint of an optical system along one or more dimensions while maintaining or improving optical performance.

In various embodiments, an optical component described herein includes a mask defining a light blocking portion and a light transmitting portion of the optical component. The light blocking portion is separated from the light transmitting portion by one or more edges of the mask. At least one of the edges of the mask is defined by an apodized pattern. As described herein, an apodized pattern is any pattern defining a gradual transition between a light blocking portion and a light transmitting portion, such that a relative density/area of the mask decreases from the light blocking portion to the light transmitting portion. For example, in various embodiments one or more edges of a mask may be defined by a repeating pattern (e.g., a sinusoidal pattern, a square wave pattern, a sawtooth pattern, etc.) along the edge, which results in a gradual transition between a light blocking portion and a light transmitting portion. In other words, an edge defined by an apodized pattern defines a transition between the light transmitting portion and the light blocking portion with a periodic pattern that repeats along the edge. Examples are illustrated and discussed in detail below.

Using a mask having at least one apodized edge may reduce flare occurring in the optical component as a result of the mask itself. In particular, apodized edges may reduce diffraction, which may reduce flare caused by the mask.

The optical component may be a prism. However, the principles of the present disclosure apply to any type of optical component. The optical component may form part of an optical system for a camera, allowing the camera to maintain focal length while reducing a size thereof along one or more dimensions, while also avoiding common performance issues with a compact optical system such as flare.

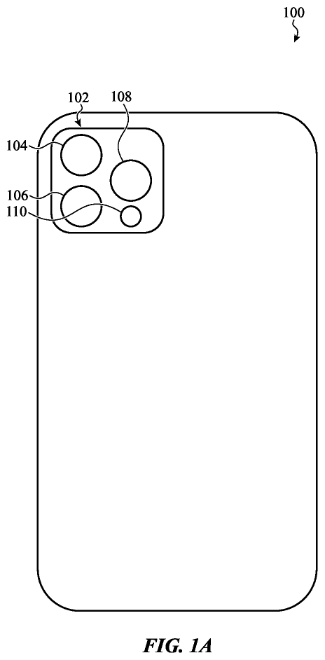

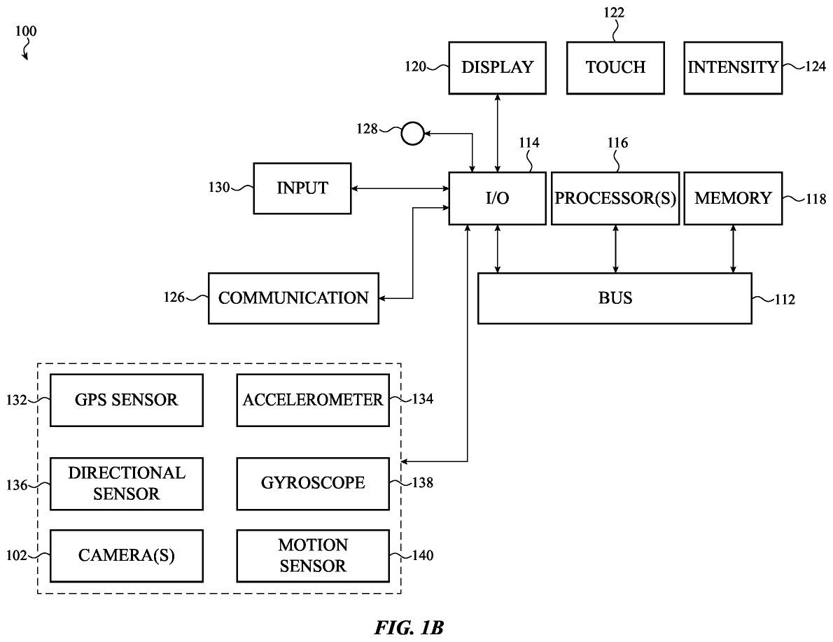

These foregoing and other embodiments are discussed below with reference to FIGS. 1A-8C. However, those skilled in the art will readily appreciate that the detailed description given herein with respect to these figures is for explanation only and should not be construed as limiting.

FIG. 1A shows a rear view of an electronic device 100 comprising a multi-camera system 102 suitable for use with the various embodiments described herein. In general, the multi-camera system 102 comprises a first camera 104 and a second camera 106. The multi-camera system 102 may optionally include one or more additional cameras (e.g., a third camera 108 as shown in FIG. 1A) and/or one or more depth sensors (e.g., depth sensor 110 as shown in FIG. 1A). While FIG. 1A shows a multi-camera system 102, it should be appreciated that the techniques described here may be utilized by any camera or cameras of a single-camera or multi-camera system.

In some embodiments, the electronic device 100 is a portable multifunction electronic device, such as a mobile telephone, that also contains other functions, such as PDA and/or music player functions. Exemplary embodiments of portable multifunction devices include, without limitation, the iPhone®, iPod Touch®, and iPad® devices from Apple Inc. of Cupertino, California. Other portable electronic devices, such as laptops or tablet computers with touch-sensitive surfaces (e.g., touch screen displays and/or touchpads), are, optionally, used. It should also be understood that, in some embodiments, the device is not a portable communications device, but is a desktop computer, which may have a touch-sensitive surface (e.g., a touch screen display and/or touchpad). In some embodiments, the electronic device is a computer system that is in communication (e.g., via wireless communication, via wired communication) with a display generation component. The display generation component is configured to provide visual output, such as display via a CRT display, display via an LED display, or display via image projection. In some embodiments, the display generation component is separate from the computer system. As used herein, “displaying” content includes causing to display the content by transmitting, via wired or wireless connection, data (e.g., image data or video data) to an integrated or external display generation component to visually produce the content.

FIG. 1B depicts exemplary components of the electronic device 100. In some embodiments, the electronic device 100 has a bus 112 that operatively couples an I/O section 114 with one or more computer processors 116 and a memory 118. The I/O section 114 can be connected to a display 120, which may have a touch-sensitive component 122 and, optionally, an intensity sensor 124 (e.g., contact intensity sensor). In addition, the I/O section 114 can be connected with a communication unit 126 for receiving application and operating system data, using, for example, Wi-Fi, Bluetooth, near field communication (NFC), cellular, and/or other wireless communication techniques. The electronic device 100 may include one or more user input mechanisms, including a first user input mechanism 128 and/or a second user input mechanism 130. The first user input mechanism 128 is, optionally, a rotatable input device or a depressible and rotatable input device, for example. The second user input mechanism 130 is, optionally, a button, in some examples. The electronic device 100 optionally includes various sensors, such as a GPS sensor 132, an accelerometer 134, a directional sensor 136 (e.g., compass), a gyroscope 138, a motion sensor 140, the multi-camera system 102, and/or a combination thereof, all of which can be operatively connected to the I/O section 114.

The memory 118 of electronic device 100 can include one or more non-transitory computer-readable storage mediums, for storing computer-executable instructions, which, when executed by one or more processors 116, for example, can cause the processors 116 to perform the techniques that are described herein. A computer-readable storage medium can be any medium that can tangibly contain or store computer-executable instructions for use by or in connection with the instruction execution system, apparatus, or device. In some examples, the storage medium is a transitory computer-readable storage medium. In some examples, the storage medium is a non-transitory computer-readable storage medium. The non-transitory computer-readable storage medium can include, but is not limited to, magnetic, optical, and/or semiconductor storages. Examples of such storage include magnetic disks, optical discs based on CD, DVD, or Blu-ray technologies, as well as persistent solid-state memory such as flash, solid-state drives, and the like.

The processor 116 can include, for example, a processor, a microprocessor, a programmable logic array (PLA), a programmable array logic (PAL), a generic array logic (GAL), a complex programmable logic device (CPLD), an application-specific integrated circuit (ASIC), a field-programmable gate array (FPGA), or any other programmable logic device (PLD) configurable to execute an operating system and applications of electronic device 100, as well as to facilitate capturing of images and in-field calibration as described herein. The processor 116 may be referred to herein as processing circuitry.

As described herein, the term “processor” and “processing circuitry” refers to any software and/or hardware-implemented data processing device or circuit physically and/or structurally configured to instantiate one or more classes or objects that are purpose-configured to perform specific transformations of data including operations represented as code and/or instructions included in a program that can be stored within, and accessed from, a memory. This term is meant to encompass a single processor or processing unit, multiple processors, multiple processing units, analog or digital circuits, or other suitably configured computing element or combination of elements. Electronic device 100 is not limited to the components and configuration of FIG. 1B, but can include other or additional components in multiple configurations.

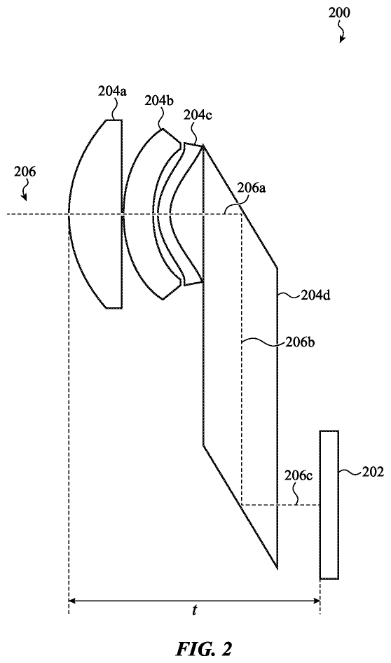

FIG. 2 shows a cross-sectional view of an exemplary optical system 200, which may be used, for example, in one of the cameras in the multi-camera system 102. For context, an image sensor 202 is shown. The optical system 200 may include a number of optical components 204 (individually 204A-204D). In particular, the optical system may include a first optical component 204A, a second optical component 204B, and a third optical component 204C, each centered along a first segment of an optical axis 206. As shown, the first optical component 204A, the second optical component 204B, and the third optical component 204C may be lenses, and thus may be configured to focus light towards and direct light along the first segment 206A of the optical axis 206. A fourth optical component 204D may be a prism, which may receive light along the first segment 206A of the optical axis 206 and fold the light one or more times along a second segment 206B and third segment 206C of the optical axis 206 to direct the light towards the image sensor 202. This may allow the optical system 200 to maintain a desirable focal length while reducing a thickness t of the optical system compared to a conventional optical system not including a prism. Accordingly, the optical system 200 may enable camera systems with desirable focal lengths in electronic devices having constrained thicknesses.

While providing the benefits of desirable focal length with reduced thickness, the optical system 200 may, in some instances, suffer from reduced performance due to the use of a folded optic. In particular, the fourth optical component 204D, depending on its design, may cause flare, which may reduce image quality in a camera system including the optical system 200.

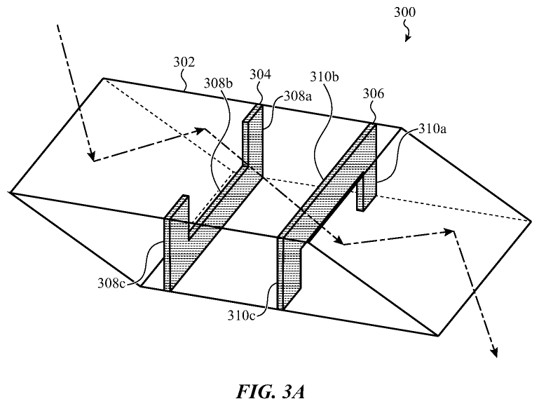

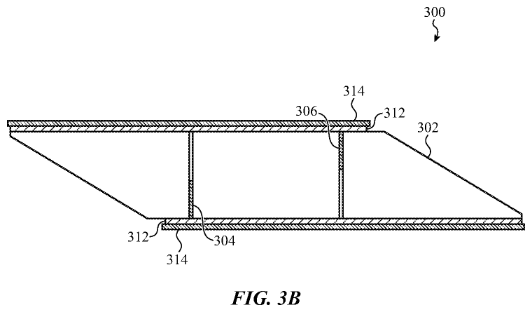

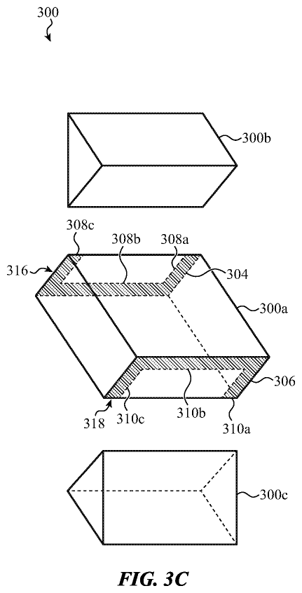

Accordingly, FIGS. 3A-3C show details of an optical component 300 for reducing flare according to one embodiment of the present disclosure. The optical component 300 may be provided as the fourth optical component 204D in FIG. 2 to form an optical system, or otherwise combined with any number of other optical components to provide an optical system. The optical component 300 includes a component body 302, which, generally, may be an optically transparent material such as plastic or glass. The component body 302 may be a prism shaped to direct light along one or more desired paths. In the embodiment shown in FIG. 3A, the optical component 300 forms a parallelogram, which redirects light along the path illustrated by the dashed arrows. However, the particular shape of the optical component 300 and the path of light traversal through the optical component 300 are merely exemplary. The principles of the present disclosure apply equally to optical components having any shape and configured to direct light along any number of different paths.

The optical component 300 may include one or more masks. In particular, the optical component 300 may include a first mask 304 in a first plane of the optical component 300 and a second mask 306 in a second plane of the optical component 300. While the first mask 304 and the second mask 306 are embedded in the optical component, the principles of the present disclosure apply equally to masks provided on a surface of an optical component. The first mask 304 may define a light blocking portion and a light transmitting portion of the plane of the optical component 300 in which it is located. The light blocking portion may be separated from the light transmitting portion by one or more mask edges 308 (individually 308A-308C). As shown, the first mask 304 may be shaped so that the light transmitting portion is rectangular, however, the principles of the present disclosure apply to masks having any shape. Similar to the first mask 304, the second mask 306 may also define a light blocking portion and a light transmitting portion of the plane of the optical component in which it is located. The light blocking portion may be separated from the light transmitting portion by one or more mask edges 310. As shown, the second mask 306 may be shaped so that the light transmitting portion is rectangular, however, the principles of the present disclosure apply to masks having any shape.

In some embodiments, the optical component 300 may include an anti-reflective (AR) or high-reflective (HR) coating at one or more exterior surfaces in order to enhance the internal reflection of light therein. For example, FIG. 3B shows a cross-sectional view of the optical component 300 in which a first coating 312 and a second coating 314 are applied to opposite parallel surfaces of the optical component 300. The first coating 312 and the second coating 314 may include an AR coating, a HR coating, or some combination thereof. The first coating 312 and the second coating 314 may enhance internal reflection of light at the surface of the optical component 300 on which they are provided. While not shown, in some embodiments the optical component 300 may include additional masks at one or more exterior surfaces thereof for further shaping light entering and/or exiting the optical component 300. In various embodiments, the first coating 312 and the second coating 314 may not necessarily cover the entire area of a surface, but rather may be patterned in any desired fashion.

FIG. 3C shows an exploded view of the optical component 300, illustrating that the optical component may be made up of one or more optical sub-components in some embodiments. In particular, the optical component 300 may include a first optical sub-component 300A, a second optical sub-component 300B, and a third optical sub-component 300C. The first optical sub-component 300A may be bonded to the second optical sub-component 300B and the third optical sub-component 300C. The first mask 304 may be on a first surface 316 of the first optical sub-component 300A such that that the first mask 304 defines a light blocking portion and a light transmitting portion of the first surface 316. The second mask 306 may be on a second surface 318 of the first optical sub-component 300A such that the second mask 306 defines a light blocking portion and a light transmitting portion of the second surface 318. The second optical sub-component 300B may be bonded to the first surface 316 of the first optical sub-component 300A, and the third optical sub-component 300C may be bonded to the second surface 318 of the first optical sub-component 300A such that the first mask 304 and the second mask 306 are embedded in the optical component 300.

Notably, bonding one or more sub-components together to embed the first mask 304 and the second mask 306 in the optical component 300 is only one exemplary way to embed masks in an optical component. The principles of the present disclosure, as they are applied to a mask embedded in an optical component, are not limited to any particular method for embedding masks in an optical component. For example, one or more masks may be embedded into a monolithic optical component (that is, an optical component formed by a single uniform piece of material), by etching a channel into a desired plane and filling the etched channel with a masking material.

The first mask 304 and the second mask 306 be configured to absorb light in one or more desired wavelengths such that the desired wavelengths of light are blocked where the first mask 304 and the second mask 306 are applied. Accordingly, the first mask 304 and the second mask 306 may reduce flare that would otherwise occur if they were excluded from the optical component 300. Those skilled in the art will appreciate that flare may occur when stray light from an external environment enters the optical system, especially stray light brighter than light from a scene or subject that a camera is supposed to capture. Flare can produce undesirable visual artifacts and thus negatively affect image quality. The first mask 304 and the second mask 306 may block light along certain reflection paths within the optical component 300 to reduce or eliminate flare that would otherwise occur if light were permitted to travel along these paths. However, the first mask 304 and the second mask 306 may themselves cause flare. In particular, the first mask 304 and the second mask 306 may cause a linear flare (i.e., a flare along a straight line) due to the way they shape light within the optical component 300.

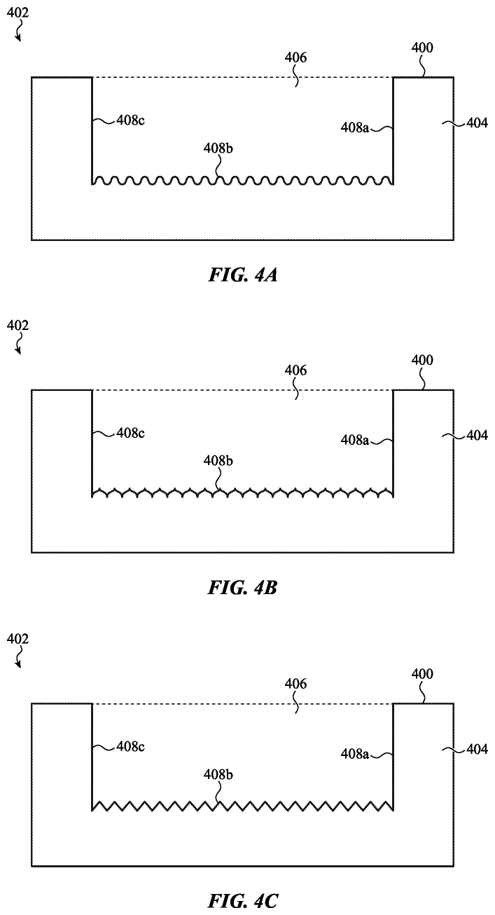

FIGS. 4A-4C illustrate various masks 400 that may reduce flare caused by the masks themselves when included in an optical component. The masks 400 illustrated in FIGS. 4A-4C may be provided as the first mask 304 and/or the second mask 306 in the optical component 300 shown in FIG. 3 in order to reduce flare caused by the masks themselves. Each of FIGS. 4A-4C shows a mask 400 located in a plane 402. The plane 402 represents the cross-sectional area of an optical component in which the mask 400 is located. As shown, each mask 400 defines a light blocking portion 404 and a light transmitting portion 406 of the plane 402. The light blocking portion 404 is separated from the light transmitting portion 406 by one or more mask edges 408. In particular, the shape of the mask 400 is such that the light blocking portion 404 is separated from the light transmitting portion 406 by a first mask edge 408A, a second mask edge 408B, and a third mask edge 408C. The mask 400 in FIGS. 4A-4C is shaped such that the resulting light transmitting portion 406 is rectangular, however, the present disclosure is not limited to masks having any particular shape.

Notably, the second mask edge 408B is defined by an apodized pattern. As discussed above, an apodized pattern is any pattern defining a gradual transition between a light blocking portion and a light transmitting portion, such that a relative density/area of the mask deceases from the light blocking portion to the light transmitting portion. For example, the second mask edge 408B may be defined by a repeating pattern, such as a sinusoidal pattern, a square wave pattern, a sawtooth pattern, or the like, along the edge. In particular, FIG. 4A shows the second mask edge 408B being defined by a sinusoidal pattern, FIG. 4B shows the second mask edge 408B being defined by an alternating cubic pattern, which is a pattern defined by a symmetric cubic function resulting in a repeating spade-like shape, and FIG. 4C shows the second mask edge 408B being defined by a sawtooth pattern. Notably, these are only a few examples of apodized patterns, and those skilled in the art will readily appreciate the myriad number of apodized patterns that may be applied to a mask edge to achieve similar results.

Providing a mask edge 408 defined by an apodized pattern may reduce diffraction at the mask edge 408, thereby reducing flare caused by the mask 400. Notably, while the second mask edge 408B is shown having an apodized pattern in FIGS. 4A-4C, any of the first mask edge 408A, the second mask edge 408B, and the third mask edge 408C may be defined by an apodized pattern. That is, any one of the first mask edge 408A, the second mask edge 408B, and the third mask edge 408C or any combination of the first mask edge 408A, the second mask edge 408B, and the third mask edge 408C may be defined by an apodized pattern.

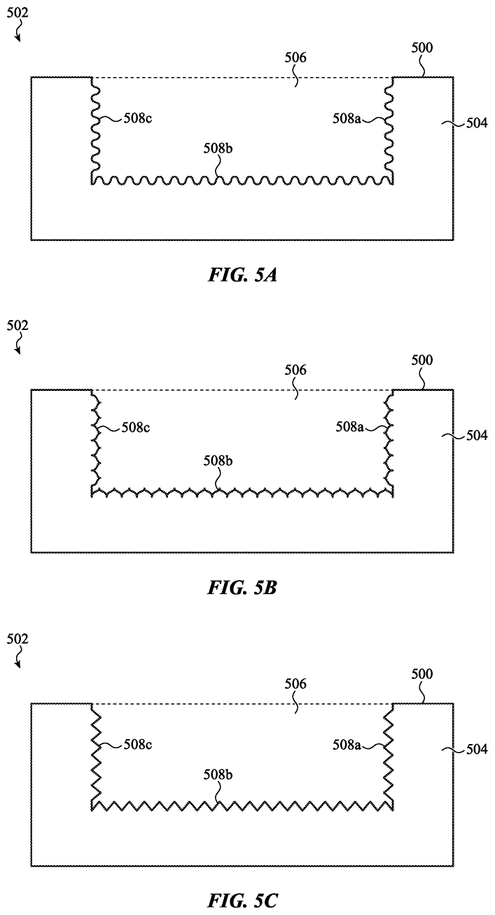

FIGS. 5A-5C similarly illustrate various masks 500 that may reduce flare caused by the masks themselves when included in an optical component. The masks 500 illustrated in FIGS. 5A-5C may be provided as the first mask 304 and the second mask 306 in the optical component 300 shown in FIG. 3 in order to reduce flare caused by the masks themselves. Each of FIGS. 5A-5C shows a mask 500 located in a plane 502. The plane 502 represents the cross-sectional area of an optical component in which the mask 500 is located. As shown, each mask 500 defines a light blocking portion 504 and a light transmitting portion 506 of the plane 502. The light blocking portion 504 is separated from the light transmitting portion 506 by one or more mask edges 508. In particular, the shape of the mask 500 is such that the light blocking portion 504 is separated from the light transmitting portion 506 by a first mask edge 508A, a second mask edge 508B, and a third mask edge 508C. The mask 500 in FIGS. 5A-5C is shaped such that the resulting light transmitting portion is rectangular, however, the present disclosure is not limited to masks having any particular shape.

Notably, the first mask edge 508A, the second mask edge 508B, and the third mask edge 508C are defined by an apodized pattern. In particular, FIG. 5A shows the first mask edge 508A, the second mask edge 508B, and the third mask edge 508C being defined by a sinusoidal pattern, FIG. 5B shows the first mask edge 508A, the second mask edge 508B, and the third mask edge 508C being defined by an alternating cubic pattern, and FIG. 5C shows the first mask edge 508A, the second mask edge 508B, and the third mask edge 508C being defined by a sawtooth pattern. As discussed above, these are only a few examples of apodized patterns, and those skilled in the art will readily appreciate the myriad number of apodized patterns that may be applied to mask edges to achieve similar results.

As discussed above, providing mask edges 508 defined by an apodized pattern may reduce diffraction at the mask edge 508, thereby reducing flare caused by the mask 500. While the same apodized pattern is shown in each mask edge 508 in FIGS. 5A-5C, different apodized patterns may also be applied to each mask edge. Further, when more than one mask is used in an optical component, a first mask may include a mask edge defined by a first apodized pattern, while a second mask may include a mask edge defined by a second apodized pattern that is different than the first apodized pattern. For example, returning to FIGS. 3A-3C, a mask edge of 308 of the first mask 304 may be defined by a first apodized pattern (e.g., a sinusoidal pattern) and a mask edge 310 of the second mask 306 may be defined by a second apodized pattern that is different than the first apodized pattern (e.g., a sawtooth pattern). Using different apodized patterns for mask edges on different masks may reduce flare caused by the masks while also providing design flexibility that may enable additional optical performance. It should be appreciated that any parameters (e.g., a period of the pattern, a peak-to-peak amplitude of the pattern, or the manner in which a period and/or peak-to-peak amplitude is varied across a mask edge) may be varied between the different masks.

In some instances, one or more parameters of a mask edge may vary along a length of the mask edge. For example, the mask edges described with respect to FIGS. 3A-5C include repeating patterns, such as a sinusoidal pattern, an alternating cubic pattern, a sawtooth pattern, a square wave pattern, or the like, that is defined by a periodic function having a peak-to-peak amplitude and a period. In some variations, the peak-to-peak amplitude and/or the period of the repeating pattern may vary along a mask edge. While a repeating pattern along a mask edge may reduce diffraction artifacts that would otherwise be caused by diffraction along a flat mask edge, some diffraction may still occur along the mask edge. Varying the peak-to-peak amplitude and/or the period of the repeating pattern along a mask edge may further reduce potential diffraction-based artifacts that may be caused by the mask edge.

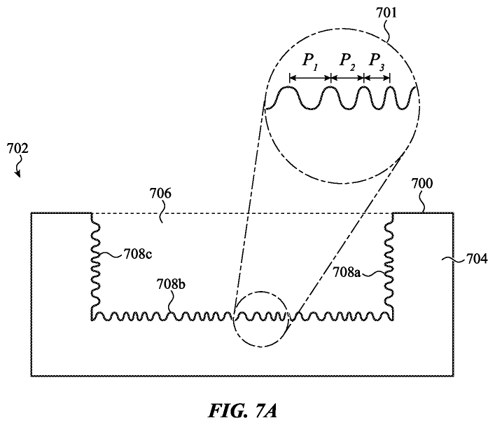

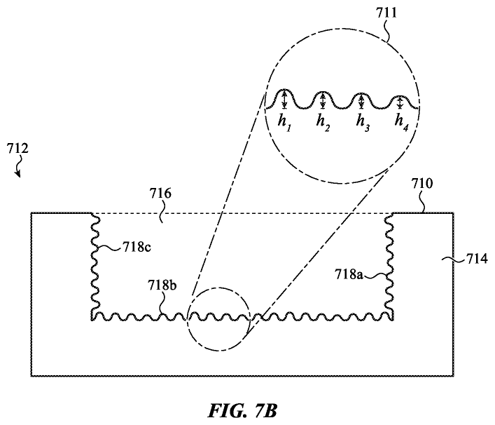

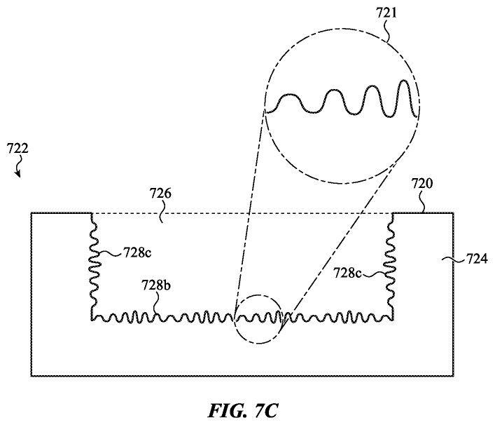

For example FIG. 7A shows an example of a mask 700 located in a plane 702 and including one or more mask edges (e.g., a first mask edge 708a, a second mask edge 708b, and a third mask edge 708c) that are defined with a repeating pattern having a varying period. The plane 702 represents the cross-sectional area of an optical component in which the mask 700 is located. The mask 700 defines a light blocking portion 704 and a light transmitting portion 706 of the plane 702, such that the one or more mask edges 708a-708c separate the light blocking portion 704 from the light transmitting portion 706.

In the variation shown in FIG. 7A, each of the first mask edge 708a, a second mask edge 708b, and a third mask edge 708c is defined by a repeating pattern having a varying period, though it should be appreciated in other instances one or more of these mask edges does not have a repeating pattern or includes a repeating pattern that does not have a varying period. Additionally, while each of the first mask edge 708a, a second mask edge 708b is shown as having a sinusoidal pattern, it should be appreciated that some or all of these mask edges may have different repeating patterns (e.g., an alternating cubic pattern, a sawtooth pattern, a square wave pattern). Additionally or alternatively, different portions of a given mask edge may have different repeating patterns (e.g., a first portion of the first mask edge 708a may have a sinusoidal pattern and a second portion of the first mask edge may have a different repeating pattern).

The period of a mask edge may vary in any suitable manner. For example, insect 701 of FIG. 7A shows a portion of the second mask edge 708b that has three different periods (P1, P2, and P₃). In some instances the period may vary according to a repeating pattern (e.g., the changes in period along one portion of a mask edge may be repeated at least once along the length of the mask edge), or may vary in a manner that is not repeated along a given mask edge. Indeed, the period of mask edge (or a portion thereof) may have a distribution of values with any desired minimum period, maximum period, and average period. Additionally, different mask edges may have different distributions of values.

For example FIG. 7B shows another example of a mask 710 located in a plane 712 including one or more mask edges (e.g., a first mask edge 718a, a second mask edge 718b, and a third mask edge 718c) that are defined with a repeating pattern having a varying peak-to-peak amplitude. The plane 712 represents the cross-sectional area of an optical component in which the mask 710 is located. The mask 710 defines a light blocking portion 714 and a light transmitting portion 716 of the plane 712, such that the one or more mask edges 718a-718c separate the light blocking portion 714 from the light transmitting portion 716.

In the variation shown in FIG. 7B, each of the first mask edge 718a, a second mask edge 718b, and a third mask edge 718c is defined by a repeating pattern having a varying peak-to-peak amplitude, though it should be appreciated that only a subset of mask edges and/or portions of these mask edges may have a varying peak-to-peak amplitude. Additionally, the first mask edge 718a, the second mask edge 718b, and/or the third mask edge 718c may include any selection or selections or repeating patterns as described herein. The peak-to-peak amplitude of a mask edge may vary in any suitable manner. For example, inset 711 shows a portion of the second mask edge 718b where the peak-to-peak amplitude changes between four values h₁, h₂, h₃, and h₄. In some instances the peak-to-peak amplitude may vary according to a repeating pattern (e.g., the changes in peak-to-peak amplitude along one portion of a mask edge may be repeated at least once along the length of the mask edge), or may vary in a manner that is not repeated along a given mask edge. Indeed, the peak-to-peak amplitude of a mask edge (or a portion thereof) may have a distribution of values with any desired minimum peak-to-peak amplitude, maximum peak-to-peak amplitude, and average peak-to-peak amplitude. Additionally, different mask edges may have different distributions of these peak-to-peak amplitude values.

In other variations, both the peak-to-peak amplitude and the period of a given mask edge pattern may vary along at least a portion of the mask edge. For example FIG. 7C shows another example of a mask 720 located in a plane 722 and including one or more mask edges (e.g., a first mask edge 728a, a second mask edge 728b, and a third mask edge 728c) that are defined with a repeating pattern having a varying peak-to-peak amplitude and a varying period. The plane 722 represents the cross-sectional area of an optical component in which the mask 720 is located. The mask 720 defines a light blocking portion 724 and a light transmitting portion 726 of the plane 722, such that the one or more mask edges 728a-728c separate the light blocking portion 724 from the light transmitting portion 726.

In the variation shown in FIG. 7C, each of the first mask edge 728a, a second mask edge 728b, and a third mask edge 728c is defined by a repeating pattern having both a varying peak-to-peak amplitude and a varying period, though it should be appreciated that only a subset of mask edges and/or portions of these mask edges may have a varying peak-to-peak amplitude and a varying period. Additionally, the first mask edge 728a, the second mask edge 728b, and/or the third mask edge 728c may include any selection or selections or repeating patterns as described herein. The peak-to-peak amplitude and the period of a mask edge may vary in any suitable manner. For example, inset 721 shows a portion of the second mask edge 728b where the peak-to-peak amplitude increases while a period decreases. In some instances one or both of period and the peak-to-peak amplitude may vary according to a repeating pattern (e.g., the changes in peak-to-peak amplitude and/or the amplitude along one portion of a mask edge may be repeated at least once along the length of the mask edge), or may vary in a manner that is not repeated along a given mask edge. Overall, the peak-to-peak amplitude of a mask edge (or a portion thereof) may have a first distribution of values with any desired minimum peak-to-peak amplitude, maximum peak-to-peak amplitude, and average peak-to-peak amplitude. Similarly, the period of mask edge (or a portion thereof) may have a second distribution of values with any desired minimum period, maximum period, and average period.

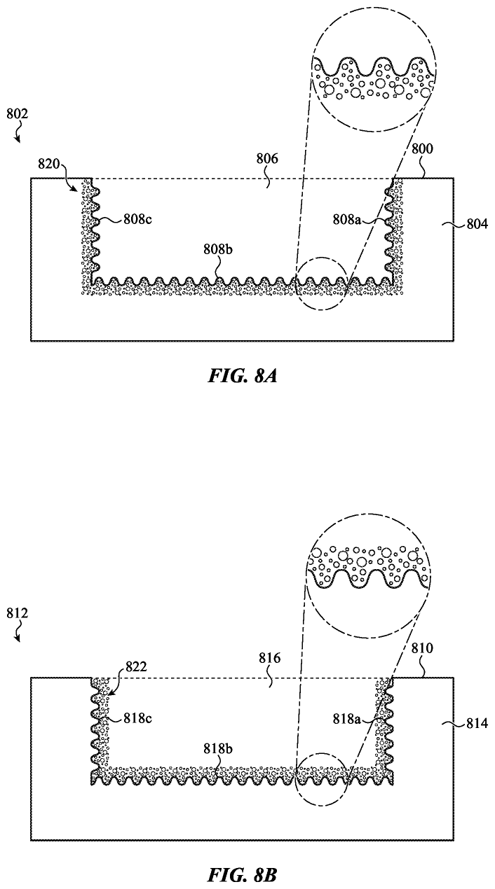

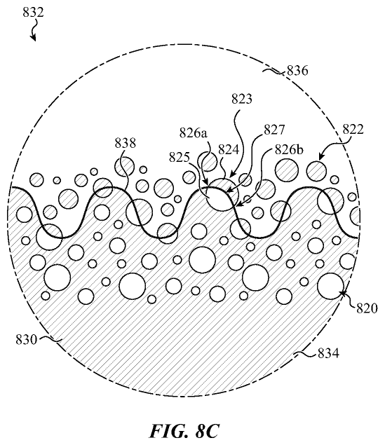

In some variations, the mask may include a distribution of apertures and/or a distribution of mask pieces that further help to reduce diffraction artifacts associated with a mask edge. For example FIG. 8A shows an example of a mask 800 located in a plane 802 including a distribution of openings 820 that are defined in (and extend through) the mask 800 and positioned adjacent to one or more mask edges (e.g., a first mask edge 808a, a second mask edge 808b, and a third mask edge 808c). For example, the distribution of openings 820 may include one or more openings positioned between different portions of the a given mask edge. Each of the first mask edge 808a, a second mask edge 808b, and a third mask edge 808c may be configured in any manner such as described herein with respect to FIGS. 4A-7C that are positioned adjacent to a distribution of openings 820 defined in the mask.

The plane 802 represents the cross-sectional area of an optical component in which the mask 800 is located. The mask 800 defines a light blocking portion 804 and a light transmitting portion 806 of the plane 802, such that the one or more mask edges 808a-808c separate the light blocking portion 804 from the light transmitting portion 806. Each opening of the distribution of openings 820 extends through the light blocking portion 804 to define an individual light transmitting region that is contained within the light blocking portion 804. Additional diffraction may occur at the edges of these openings, which may, in turn, mitigate or otherwise alter diffraction artifacts that may otherwise occur from the mask edges.

The distribution of openings 820 may include openings having any suitable sizes, shapes (e.g., circular, elliptical, rectangular, or the like), and relative positioning as may be desired. Overall, it may be desirable to locally vary (e.g., within a given region of the distribution of openings) some or all of size, shape, and relative position of the individual openings. In some instances, the size of the openings may vary across the distribution and/or the shape of the openings may vary across the distribution. Additionally or alternatively, the spacing of these openings may vary across the distribution. In some instances, the distribution of openings 820 may follow an irregular pattern, such as a pattern that does not repeat along a mask edge, or a pattern that repeats less than a threshold number of times along a given mask edge, as this may help to reduce artifacts that may result from periodicity of the distribution of openings 820.

In some variations a region of the distribution of openings 820 may be configured such that the relative density of the openings (e.g., a relative ratio between the area of the light transmitting regions and light blocking regions within the light blocking portion 804) increases or decreases in a given direction relative to a given mask edge. The distribution of openings 820 may be formed simultaneously with the rest of the mask 800 (e.g., using the same process that forms the first, second, and third mask edges 808a-808c), or may be later defined in the mask (e.g., after the first, second, and third mask edges 808a-808c are already formed).

FIG. 8B shows an example of a mask 810 located in a plane 812 and including a distribution of mask pieces 822 that are positioned adjacent to one or more mask edges (e.g., a first mask edge 818a, a second mask edge 818b, and a third mask edge 818c). For example, the distribution of mask pieces 822 may include one or more mask pieces positioned between different portions of a given mask edge. Each of the first mask edge 818a, a second mask edge 818b, and a third mask edge 818c may be configured in any manner such as described herein with respect to FIGS. 4A-7C that are positioned adjacent to a distribution of mask pieces 822 positioned in the light transmitting portion 816.

The plane 812 represents the cross-sectional area of an optical component in which the mask 800 is located. The mask 810 defines a light blocking portion 814 and a light transmitting portion 816 of the plane 812, such that the one or more mask edges 818a-818c separate the light blocking portion 814 from the light transmitting portion 816. Each mask piece of the distribution of mask pieces 822 includes a segment of light blocking material (e.g., which may be the same material or a different material as that forming the light blocking portion 814) to define an individual light blocking region that is contained within the light transmitting portion 816. Additional diffraction may occur at the edges of these mask pieces, which may, in turn, mitigate or otherwise alter diffraction artifacts that may otherwise occur from the mask edges.

The distribution of mask pieces 822 may include mask pieces having any suitable sizes, shapes (e.g., circular, elliptical, rectangular, or the like), and relative positioning as may be desired. Overall, it may be desirable to locally vary (e.g., within a given region of the distribution of mask pieces) some or all of size, shape, and relative position of the individual mask pieces. In some instances, the size of the mask pieces may vary across the distribution and/or the shape of the mask pieces may vary across the distribution. Additionally or alternatively, the spacing of these mask pieces may vary across the distribution. In some instances, the distribution of mask pieces 822 may follow an irregular pattern, such as a pattern that does not repeat along a mask edge, or a pattern that repeats less than a threshold number of times along a given mask edge, as this may help to reduce artifacts that may result from periodicity of the distribution of mask pieces 822.

In some variations, a region of the distribution of mask pieces 822 may be configured such that the relative density of the mask pieces (e.g., a relative ratio between the area of the light transmitting regions and light blocking regions within the light transmitting portion 816) increases or decreases in a given direction relative to a given mask edge. It should be appreciated that in some variations, a mask may include both a distribution of mask openings (e.g., the distribution of openings 820 of FIG. 8A) and a distribution of mask pieces (e.g., the distribution of mask pieces 822 of FIG. 8B).

In some variations, an apodized pattern of a mask edge (such as those described with respect to FIGS. 4A-5C and 7A-7C) may be partially formed by one or more inverted mask regions. In these instances, each inverted mask region is defined by a pair including i) a mask piece and ii) an opening defined to extend through the mask, such that an interface between the mask piece and the opening form a portion of the apodized pattern. For example, FIG. 8C shows a portion of one such variation of a mask 830. The mask 830 is positioned within a plane 832, which represents the cross-sectional area of an optical component in which the mask 830 is located.

The mask 830 defines a light blocking portion 834 and a light transmitting portion 836 of the plane 832, such that a mask edge 838 (which may be any of the mask edges described herein) separates the light blocking portion 834 from the light transmitting portion 836. The mask edge 838 may have an apodized pattern, such as those described herein. For example, the mask edge 838 is shown in FIG. 8C as being defined by a sinusoidal pattern. Also shown in FIG. 8C is an inverted mask region 823 that includes a mask piece 824 and an opening 825 that extends through the mask 830, where the inverted mask region 823 defines a portion of the mask edge 838. Specifically, the mask piece 824 may be configured as described above with respect to the mask pieces of FIG. 8B, except that the mask piece 824 contacts the mask 830 at a pair of contact points (e.g., a first contact point 826a and a second contact point 826b), and may thereby at least partially define the opening 825. Specifically, the opening 825 may be defined by i) a portion of the mask 830 that extends between the first contact point 826a and the second contact point 826b), and ii) a side of the mask piece 824 extending between the first contact point 826a and the second contact point 826b. The side of the mask piece 824 extending between the first contact point 826a and the second contact point 826b forms an interface 827 between the mask piece 824 and the opening 825.

The mask piece 824 and the opening 825 collectively act to invert the mask 830 along the interface 827. Specifically, the mask piece 824 forms an individual light blocking region (defined by the boundaries of the mask piece 824) that contacts the light blocking portion 834 at each of the first contact point 826a and the second contact point 826b. Similarly, the opening 825 forms an individual light transmitting region that contacts the light transmitting portion 836 at each of the first contact point 826a and the second contact point 826b. The interface 827 between the mask piece 824 and the opening 825 may be considered part of the mask edge 838, and may follow the apodized pattern. The presence of inverted mask regions may further help to reduce diffraction artifacts that may be otherwise associated with the mask edge 838 having the same apodized pattern (but without the inverted mask regions).

In the variation shown in FIG. 8C, the inverted mask region 823 has a circular shape (e.g., the respective shapes of the mask piece 824 and the opening 825 collectively form a circular shape), though it should be appreciated that the inverted mask region 823 may have any suitable shape (e.g., elliptical, rectangular, or the like). To the extent that the mask 830 includes multiple inverted mask regions positioned along the mask edge 838, different inverted mask regions may have the same size and shape or different sizes and/or shapes. It should be also appreciated that in some variations, the mask 830 may include a distribution of openings 820, such as described herein with respect to FIG. 8A, that are fully contained within the light blocking portion 834. Additionally or alternatively, the mask 830 may further include a distribution of mask pieces 822, such as described herein with respect to FIG. 8B, that are fully contained within the light transmitting portion 836.

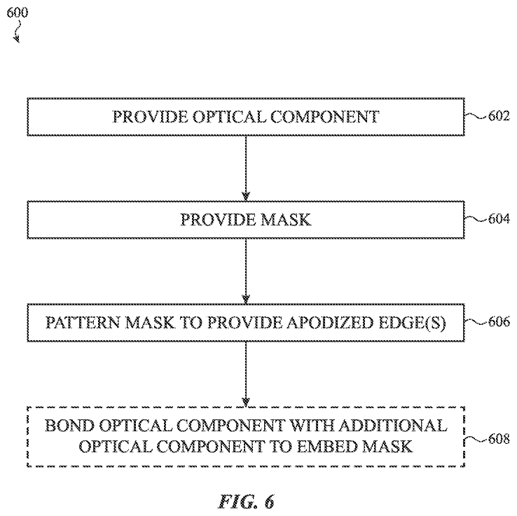

FIG. 6 is a flowchart depicting example operations of a method 600 for manufacturing an optical component including a mask having an apodized mask edge according to one embodiment of the present disclosure. At block 602, an optical component is provided. Providing the optical component may include manufacturing the optical component (e.g., by mechanical or laser cutting of a glass wafer, or by any other suitable process). At block 604, a mask is provided. Providing the mask may include coating a surface of the optical component with a masking material (e.g., titanium oxide, mixed metal oxides, metals, metal nitrides, carbides, or the like) in a physical vapor deposition process, a chemical vapor deposition process, an atomic layer deposition process, or any other suitable process. In other embodiments, providing the mask may include providing glass black frit over a surface of the optical component and sintering. At block 606, the mask is patterned to provide one or more edges defined by an apodized pattern as discussed above. This may include, for example, lithography-based etching of a deposited mask layer or laser ablating a desired apodized pattern in a deposited mask layer. In some embodiments, this may include etching the optical component or laser drilling.

Notably, in some embodiments blocks 604 and 606 are combined such that the mask is provided in a patterned fashion. For example, a patterned stencil may be provided on a surface of the optical component, a mask layer deposited over the stencil, and the stencil lifted off. As another example, mask material may be screen printed in a desired pattern using a stencil. As another example, a patterned mask may be provided using nano-imprint lithography. As yet another example, a mask layer whose properties can be changed by laser blackening may be applied, and subsequently blackened in a desired pattern with a laser. Finally, but not exhaustively, a mask having a desired shape may be formed during the manufacture of the optical component itself (e.g., via embedded elements provided during manufacture of structured glass). Those skilled in the art will appreciate that the exemplary methods for providing a patterned mask discussed above are not exhaustive, but are merely meant to provide a broad overview of the ways in which a mask including an apodized edge could be provided.

The above process may be repeated any number of times to provide multiple masks. As discussed above, each of the masks may be provided such that mask edges of different masks are defined by different apodized patterns. For example, a mask edge of a first mask may be defined by a first apodized pattern, and a mask edge of a second mask may be defined by a second apodized pattern that is different than the first apodized pattern.

In some embodiments, a mask is provided on a surface of an optical component, and it may be desired to embed the mask within the optical component. Accordingly, at block 608, the optical component may be bonded with an additional optical component to embed the mask in the resulting combined optical component. In particular, the additional optical component may be bonded to the surface on which the mask was provided. The optical components may be bonded by any suitable process. In one embodiment, a backfill process may be performed wherein a coating is applied to the surface of the optical component to be bonded in order to improve bonding with the additional optical component. The coating may include silicon oxide, titanium oxide, barium oxide, aluminum oxide, sodium fluoride, a silicon oxide/niobium pentoxide mixture, or any other suitable material(s). In some embodiments, a pre-activation process may be performed prior to the backfill process, wherein plasma, chemical absorption, or deposition of a reactive component or terminal group by surface functionalization may be added as a way to further improve bonding with the additional optical component. The treated surface of the optical component may be polished and bonded with the additional optical component. The bonding may be a non-adhesive bonding process such as a fusion bonding process, an anodic bonding process, or a reactive bonding process. In other embodiments, the bonding is performed via an adhesive bonding process. Those skilled in the art will appreciate that the exemplary methods for bonding optical components discussed above are not exhaustive, but are merely meant to provide a broad overview of the ways in which optical components could be bonded.

These foregoing embodiments depicted in FIGS. 1A-8C and the various alternatives thereof and variations thereto are presented, generally, for purposes of explanation, and to facilitate an understanding of various configurations and constructions of a system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

1. An optical component, comprising:
a component body comprising an optically transparent material; and
a mask defining a light blocking portion and a light transmitting portion of a plane of the component body, the light blocking portion of the plane being separated from the light transmitting portion of the plane by one or more edges of the mask, at least one of the one or more edges of the mask being defined by an apodized pattern.

2. The optical component of claim 1, wherein the light transmitting portion of the plane is rectangular.

3. The optical component of claim 1, wherein the component body comprises glass.

4. The optical component of claim 1, wherein the light blocking portion of the plane is separated from the light transmitting portion of the plane by a first mask edge and a second mask edge.

5. The optical component of claim 4, wherein:
the first mask edge is defined by the apodized pattern; and
the second mask edge is defined by a straight line.

6. The optical component of claim 4, wherein the first mask edge and the second mask edge are defined by the apodized pattern.

7. The optical component of claim 1, further comprising:
an additional mask defining a light blocking portion and a light transmitting portion of an additional plane of the component body, the light blocking portion of the additional plane being separated from the light transmitting portion of the additional plane by one or more edges of the additional mask, at least one of the one or more edges of the additional mask being defined by an apodized pattern.

8. The optical component of claim 7, wherein the at least one of the one or more edges of the mask is defined by a different apodized pattern than the at least one of the one or more edges of the additional mask.

9. The optical component of claim 7, wherein the additional plane is parallel to the plane.

10. The optical component of claim 7, wherein the optical component is a prism.

11. The optical component of claim 1, wherein the apodized pattern is a repeating pattern with a varying peak-to-peak amplitude.

12. The optical component of claim 1, wherein the apodized pattern is a repeating pattern with a varying period.

13. The optical component of claim 1, wherein the mask comprises a distribution of openings positioned in the light blocking portion.

14. The optical component of claim 1, wherein the mask comprises a distribution of mask pieces positioned in the light transmitting portion.

15. An optical component, comprising:
a first optical sub-component;
a mask on a surface of the first optical sub-component, the mask defining a light blocking portion of the surface and a light transmitting portion of the surface, the light blocking portion of the surface being separated from the light transmitting portion of the surface by one or more edges of the mask, at least one of the one or more edges of the mask being defined by an apodized pattern; and
a second optical sub-component bonded to the surface of the first optical sub-component such that the mask is embedded between the first optical sub-component and the second optical sub-component.

16. The optical component of claim 15, wherein the light transmitting portion of the surface is rectangular.

17. The optical component of claim 15, wherein the first optical sub-component and the second optical sub-component comprise glass.

18. The optical component of claim 15, wherein the light blocking portion of the surface is separated from the light transmitting portion of the surface by a first mask edge and a second mask edge.

19. The optical component of claim 18, wherein:
the first mask edge is defined by the apodized pattern; and
the second mask edge is defined by a straight line.

20-30. (canceled)

31. A camera, comprising:
an aperture;
an image sensor; and
an optical component between the aperture and the image sensor, the optical component configured to direct light from the aperture towards the image sensor, the optical component comprising:
a component body comprising an optically transparent material; and
a mask defining a light blocking portion and a light transmitting portion of a plane of the component body, the light blocking portion of the plane being separated from the light transmitting portion of the plane by one or more edges of the mask, at least one of the one or more edges of the mask being defined by an apodized pattern.
